(19) United States
(12) Patent Application Publication
(10) Pub. No.: US 2023/0307599 A1
(43) Pub. Date: Sep. 28, 2023

(54) LIGHT-EMITTING DEVICE, PROJECTOR, DISPLAY, AND HEAD-MOUNTED DISPLAY

(71) Applicant: SEIKO EPSON CORPORATION, Tokyo (JP)

(72) Inventor: Shinji TERAO, Fujimi-Machi (JP)

(73) Assignee: SEIKO EPSON CORPORATION, Tokyo (JP)

(21) Appl. No.: 18/124,243

(22) Filed: Mar. 21, 2023

(30) Foreign Application Priority Data
Mar. 22, 2022 (JP) 2022-045271

(51) Int. Cl. H01L 33/62; H01L 25/16

(52) U.S. Cl. CPC H01L 33/62; H01L 25/167

(57) ABSTRACT

A light-emitting device includes a substrate; a first semiconductor portion having a first conductivity type; a first columnar portion and a second columnar portion each including a second semiconductor portion having a second conductivity type different from the first conductivity type, a third semiconductor portion having the first conductivity type, and a quantum well layer; a first electrode; a second electrode; and a conductive member electrically coupling the second electrode and the first semiconductor portion. Each of the first columnar portion and the second columnar portion protrudes from the first semiconductor portion toward a side of the substrate. The first electrode is electrically coupled to the second semiconductor portion of the first columnar portion. The second electrode is electrically coupled to, via the conductive member and the first semiconductor portion, the third semiconductor portion of the first columnar portion.

The present application is based on, and claims priority from JP Application Serial Number 2022-045271, filed Mar. 22, 2022, the disclosure of which is hereby incorporated by reference herein in its entirety.

### BACKGROUND

### 1. Technical Field

The present disclosure relates to a light-emitting device, a projector, a display, and a head-mounted display.

### 2. Related Art

A semiconductor laser is expected as a next-generation light source with high luminance. In particular, a semiconductor laser to which nanocolumns are applied is expected to be capable of realizing high-output light emission at a narrow radiation angle by an effect of a photonic crystal due to a periodic arrangement of the nanocolumns.

For example, JP-A-2020-161620 describes a light-emitting device including a buffer layer, a columnar portion provided at the buffer layer, a first electrode provided at the buffer layer, and a second electrode provided at the columnar portion. The columnar portion includes an n-type first semiconductor layer, a p-type second semiconductor layer, and a light-emitting layer provided between the first semiconductor layer and the second semiconductor layer.

In the light-emitting device as described above, flip-chip mounting is known. In a stacking direction of the first semiconductor layer and the light-emitting layer, when a difference between a position of a surface of a first electrode on a side opposite to the buffer layer and a position of a surface of a second electrode on a side opposite to the buffer layer is large, it is difficult to perform the flip-chip mounting.

### SUMMARY

A light-emitting device according to an aspect of the present disclosure includes: a substrate, a first semiconductor portion having a first conductivity type, a first columnar portion and a second columnar portion each including a second semiconductor portion having a second conductivity type different from the first conductivity type, a third semiconductor portion having the first conductivity type and provided between the first semiconductor portion and the second semiconductor portion, and a quantum well layer provided between the second semiconductor portion and the third semiconductor portion, a first electrode provided between the first columnar portion and the substrate, a second electrode provided between the second columnar portion and the substrate, and a conductive member electrically coupling the second electrode and the first semiconductor portion, wherein each of the first columnar portion and the second columnar portion protrudes from the first semiconductor portion toward a side of the substrate, the second semiconductor portion is provided between the substrate and the quantum well layer, the first electrode is electrically coupled to the second semiconductor portion of the first columnar portion, and the second electrode is electrically coupled to, via the conductive member and the first semiconductor portion, the third semiconductor portion of the first columnar portion.

An aspect of a projector according to the present disclosure includes the light-emitting device according to the aspect of the disclosure.

An aspect of a display according to the present disclosure includes the light-emitting device according to the aspect of the disclosure.

An aspect of a head-mounted display according to the present disclosure includes the light-emitting device according to the aspect of the disclosure.

### BRIEF DESCRIPTION OF THE DRAWINGS

FIG. 1 is a cross-sectional view schematically illustrating a light-emitting device according to a first exemplary embodiment.

FIG. 2 is a plan view schematically illustrating the light-emitting device according to the first exemplary embodiment.

FIG. 3 is a cross-sectional view schematically illustrating a manufacturing process of the light-emitting device according to the first exemplary embodiment.

FIG. 4 is a cross-sectional view schematically illustrating the manufacturing process of the light-emitting device according to the first exemplary embodiment.

FIG. 5 is a cross-sectional view schematically illustrating the manufacturing process of the light-emitting device according to the first exemplary embodiment.

FIG. 6 is a cross-sectional view schematically illustrating the manufacturing process of the light-emitting device according to the first exemplary embodiment.

FIG. 7 is a cross-sectional view schematically illustrating the manufacturing process of the light-emitting device according to the first exemplary embodiment.

FIG. 8 is a cross-sectional view schematically illustrating the manufacturing process of the light-emitting device according to the first exemplary embodiment.

FIG. 9 is a cross-sectional view schematically illustrating the manufacturing process of the light-emitting device according to the first exemplary embodiment.

FIG. 10 is a cross-sectional view schematically illustrating a light-emitting device according to a second exemplary embodiment.

FIG. 11 is a plan view schematically illustrating the light-emitting device according to the second exemplary embodiment.

FIG. 12 is a cross-sectional view schematically illustrating a manufacturing process of the light-emitting device according to the second exemplary embodiment.

FIG. 13 is a cross-sectional view schematically illustrating the manufacturing process of the light-emitting device according to the second exemplary embodiment.

FIG. 14 is a cross-sectional view schematically illustrating the manufacturing process of the light-emitting device according to the second exemplary embodiment.

FIG. 15 is a cross-sectional view schematically illustrating the manufacturing process of the light-emitting device according to the second exemplary embodiment.

FIG. 16 is a cross-sectional view schematically illustrating the manufacturing process of the light-emitting device according to the second exemplary embodiment.

FIG. 17 is a cross-sectional view schematically illustrating the manufacturing process of the light-emitting device according to the second exemplary embodiment.

FIG. 18 is a cross-sectional view schematically illustrating the manufacturing process of the light-emitting device according to the second exemplary embodiment.

FIG. 19 is a cross-sectional view schematically illustrating the manufacturing process of the light-emitting device according to the second exemplary embodiment.

FIG. 20 is a cross-sectional view schematically illustrating the manufacturing process of the light-emitting device according to the second exemplary embodiment.

FIG. 21 is a cross-sectional view schematically illustrating the manufacturing process of the light-emitting device according to the second exemplary embodiment.

FIG. 22 is a cross-sectional view schematically illustrating the manufacturing process of the light-emitting device according to the second exemplary embodiment.

FIG. 23 is a cross-sectional view schematically illustrating the manufacturing process of the light-emitting device according to the second exemplary embodiment.

FIG. 24 is a cross-sectional view schematically illustrating the manufacturing process of the light-emitting device according to the second exemplary embodiment.

FIG. 25 is a diagram schematically illustrating a projector according to a third exemplary embodiment.

FIG. 26 is a plan view schematically illustrating a display according to a fourth exemplary embodiment.

FIG. 27 is a cross-sectional view schematically illustrating the display according to the fourth exemplary embodiment.

FIG. 28 is a perspective view schematically illustrating a head-mounted display according to a fifth exemplary embodiment.

FIG. 29 is a diagram schematically illustrating an image forming device and a light guide device of the head-mounted display according to the fifth exemplary embodiment.

### DESCRIPTION OF EXEMPLARY EMBODIMENTS

Hereinafter, preferred exemplary embodiments of the present disclosure will be described in detail with reference to the drawings. Note that the exemplary embodiment described hereinafter is not intended to unjustly limit the content of the present disclosure as set forth in the claims. In addition, all of the configurations described below are not necessarily essential components of the disclosure.

### 1. First Exemplary Embodiment

### 1.1. Light-Emitting Device

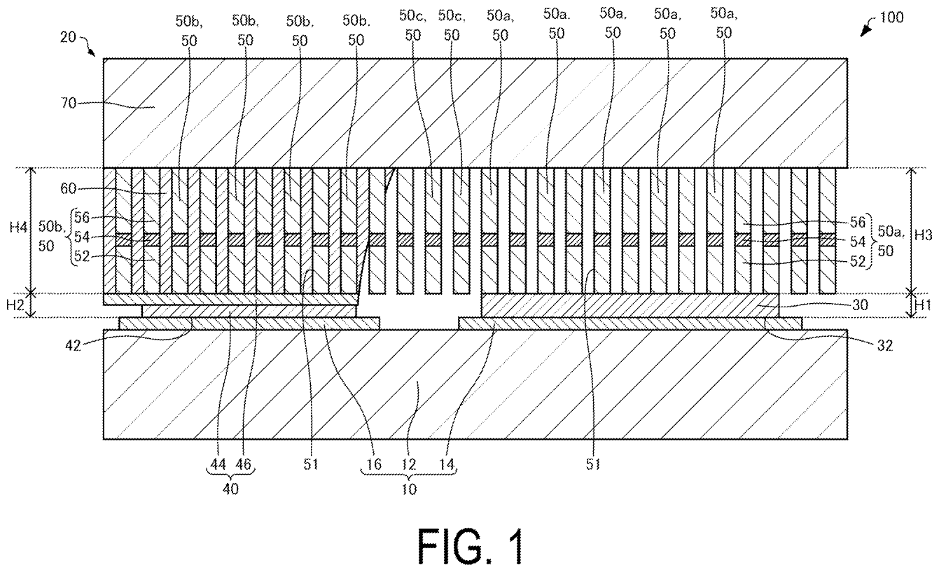

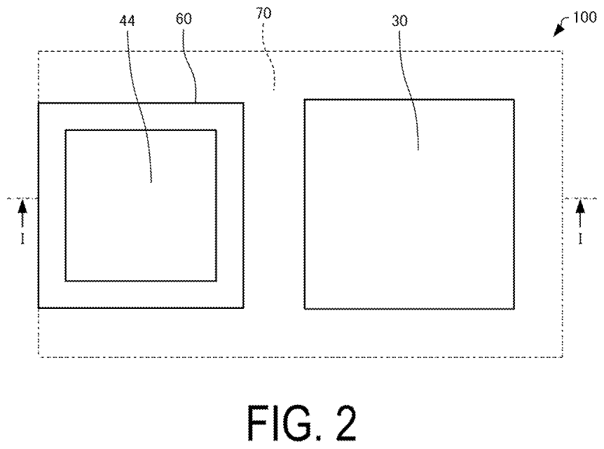

First, a light-emitting device according to a first exemplary embodiment will be described with reference to the drawings. FIG. 1 is a cross-sectional view schematically illustrating a light-emitting device 100 according to the first exemplary embodiment. FIG. 2 is a plan view schematically illustrating the light-emitting device 100 according to the first exemplary embodiment. FIG. 1 is a cross-sectional view taken along line I-I of FIG. 2.

As illustrated in FIGS. 1 and 2, the light-emitting device 100 includes, for example, a substrate 10 and a light-emitting element 20. For convenience, in FIG. 2, members other than a first electrode 30, a first metal layer 44, a conductive member 60, and a first semiconductor portion 70 of the light-emitting element 20 are not illustrated. In FIG. 2, an outer edge of the conductive member 60 is illustrated. In FIG. 2, the first semiconductor portion 70 is illustrated in a see-through manner.

As illustrated in FIG. 1, the substrate 10 includes, for example, a circuit board 12, a first bump 14, and a second bump 16.

The circuit board 12 is electrically coupled to the light-emitting element 20 via the bumps 14, 16. The circuit board 12 is configured to include a drive circuit that drives the light-emitting element 20. The drive circuit is formed of, for example, an integrated circuit (IC). The circuit board 12 is provided with first wiring and second wiring (not illustrated). The drive circuit and the first electrode 30 are electrically coupled by the first wiring (not illustrated). The drive circuit and a second electrode 40 are electrically coupled by the second wiring (not illustrated).

The first bump 14 and the second bump 16 are provided at the circuit board 12. The bumps 14, 16 are provided between the circuit board 12 and the light-emitting element 20. The bumps 14, 16 are spaced apart from each other. The material of the bumps 14, 16 is, for example, copper or gold.

In “1.1. Light-emitting Device”, in a stacking direction of a second semiconductor portion 52 and a quantum well layer 54 of a columnar portion 50 of the light-emitting element 20 (hereinafter, also simply referred to as “stacking direction”), when the quantum well layer 54 is used as a reference, a direction from the quantum well layer 54 toward the third semiconductor portion 56 of the columnar portion 50 is described as “up”, and a direction from the quantum well layer 54 toward the second semiconductor portion 52 is described as “down”. The direction orthogonal to the stacking direction is also referred to as an “in-plane direction”.

The light-emitting element 20 is provided at the substrate 10. The light-emitting element 20 includes the first electrode 30, the second electrode 40, the columnar portion 50, the conductive member 60, and the first semiconductor portion 70. The light-emitting element 20 is flip-chip mounted with the electrodes 30, 40 side facing the substrate 10. Therefore, in the light-emitting device 100, it is not necessary to establish conduction between the electrode and the circuit board by using, for example, wire bonding, and it is possible to achieve a reduction in size.

The first electrode 30 is provided at the first bump 14. The first electrode 30 is bonded to, for example, the first bump 14. The first electrode 30 is provided between the first bump 14 and the columnar portion 50. In the example illustrated in FIG. 2, the planar shape of the first electrode 30 is a quadrangle such as a square or a rectangle, but may be a circle or a polygon other than a quadrangle. The first electrode 30 is, for example, a metal layer having a large work function, such as a gold layer or a nickel layer, or a laminate thereof.

As illustrated in FIG. 1, the first electrode 30 includes a first surface 32. The first surface 32 is a surface of the first electrode 30 on a side opposite to the first semiconductor portion 70. The first surface 32 is a surface of the first electrode 30 on the substrate 10 side. The first surface 32 is an end of the first electrode 30 on the substrate 10 side. In the illustrated example, the first surface 32 is a lower surface of the first electrode 30.

The second electrode 40 is provided at the second bump 16. The second electrode 40 is bonded to the second bump 16 via, for example, solder (not illustrated). The second electrode 40 is provided between the second bump 16, and the columnar portion 50 and the conductive member 60.

The second electrode 40 includes a second surface 42. The second surface 42 is a surface of the second electrode 40 on a side opposite to the first semiconductor portion 70. The second surface 42 is a surface of the second electrode 40 on the substrate 10 side. The second surface 42 is an end of the second electrode 40 on the substrate 10 side. In the illustrated example, the second surface 42 is a lower surface of the second electrode 40. The second electrode 40 includes, for example, the first metal layer 44 and a second metal layer 46.

The first metal layer 44 of the second electrode 40 is provided at the second bump 16. The first metal layer 44 is bonded to the second bump 16. The first metal layer 44 is provided between the second bump 16 and the second metal layer 46. In the example illustrated in FIG. 2, the planar shape of the first metal layer 44 is a quadrangle such as a square or a rectangle, but may be a circle or a polygon other than a quadrangle. The first metal layer 44 is, for example, a gold layer, a nickel layer, an aluminum layer, a titanium layer, or a laminate of these layers.

As illustrated in FIG. 1, the second metal layer 46 of the second electrode 40 is provided at the first metal layer 44. The second metal layer 46 is provided between the first metal layer 44, and the columnar portion 50 and the conductive member 60. The first metal layer 44 is provided inside the second metal layer 46 when viewed from the stacking direction. The second metal layer 46 is, for example, a platinum layer. For example, the first metal layer 44 is in contact with the conductive member 60, and may be formed of the same material as the conductive member 60 at the same time. The material of the second metal layer 46 and the material of the first metal layer 44 may be different from each other.

The second electrode 40 is spaced apart from the first electrode 30. A height H1 of the first electrode 30 and a height H2 of the second electrode 40 are, for example, the same. The “height” refers to the size in the stacking direction. In the illustrated example, a distance between the first surface 32 of the first electrode 30 and the first semiconductor portion 70 is the same as a distance between the second surface 42 of the second electrode 40 and the first semiconductor portion 70.

The columnar portion 50 is provided between the substrate 10 and the first semiconductor portion 70. The columnar portion 50 protrudes from the first semiconductor portion 70 toward the substrate 10 side. The columnar portion 50 is also called, for example, a nanocolumn, a nanowire, a nanorod, or a nanopillar. The planar shape of the columnar portion 50 is, for example, a circle or a polygon such as a regular hexagon.

The diameter of the columnar portions 50 is, for example, from 50 nm to 500 nm. By setting the diameter of the columnar portion 50 to be less than or equal to 500 nm, it is possible to obtain the quantum well layer 54 of a high-quality crystal and to reduce the strain in the quantum well layer 54.

The “diameter of the columnar portion 50” is a diameter when the planar shape of the columnar portion 50 is a circle, and is a diameter of a minimum inclusion circle when the planar shape of the columnar portion 50 is not a circle. For example, when the planar shape of the columnar portion 50 is a polygon, the diameter of the columnar portion 50 is the diameter of the smallest circle including the polygon therein, and when the planar shape of the columnar portion 50 is an ellipse, the diameter of the columnar portion 50 is the diameter of the smallest circle including the ellipse therein.

A plurality of the columnar portions 50 are provided. The plurality of columnar portions 50 are separated from each other. The interval between the adjacent columnar portions 50 is, for example, from 5 nm to 30 nm. When the space between the adjacent columnar portions 50 is filled with the insulating layer, the interval between the adjacent columnar portions 50 may be as wide as 200 nm. The plurality of columnar portions 50 are arranged at a predetermined pitch in a predetermined direction when viewed from the stacking direction. The plurality of columnar portions 50 are arranged in, for example, a regular triangular lattice shape or a square lattice shape. The plurality of columnar portions 50 can exhibit an effect of a photonic crystal.

The “pitch of the columnar portions 50” is a distance between the centers of the columnar portions 50 adjacent to each other in a predetermined direction. The “center of the columnar portion 50” is a center of a circle when the planar shape of the columnar portion 50 is a circle, and is a center of a minimum inclusion circle when the planar shape of the columnar portion 50 is not a circle. For example, when the planar shape of the columnar portion 50 is a polygon, the center of the columnar portion 50 is a center of the smallest circle including the polygon therein, and when the planar shape of the columnar portion 50 is an ellipse, the center of the columnar portion 50 is a center of the smallest circle including the ellipse therein.

The columnar portion 50 includes the second semiconductor portion 52, the quantum well layer 54, and the third semiconductor portion 56. In the illustrated example, the columnar portion 50 is composed of the second semiconductor portion 52, the quantum well layer 54, and the third semiconductor portion 56. The second semiconductor portion 52, the quantum well layer 54, and the third semiconductor portion 56 are, for example, group III nitride semiconductors, and have a wurtzite crystal structure.

The second semiconductor portion 52 is provided between the substrate 10 and the quantum well layer 54. The second semiconductor portion 52 is a semiconductor layer having a second conductivity type different from a first conductivity type. The second conductivity type is, for example, p-type. The second semiconductor portion 52 is, for example, a p-type GaN layer doped with Mg.

The quantum well layer 54 is provided at the second semiconductor portion 52. The quantum well layer 54 is provided between the second semiconductor portion 52 and the third semiconductor portion 56. The quantum well layer 54 includes, for example, a well layer and a barrier layer. The well layer and the barrier layer are i-type semiconductor layers that are not intentionally doped with impurities. The well layer is, for example, an InGaN layer. The barrier layer is, for example, a GaN layer. The quantum well layer 54 has a multiple quantum well (MQW) structure composed of a well layer and a barrier layer.

The number of well layers and barrier layers constituting the quantum well layer 54 is not particularly limited. For example, only one well layer may be provided, and in this case, the quantum well layer 54 has a single quantum well (SQW) structure.

The third semiconductor portion 56 is provided at the quantum well layer 54. The third semiconductor portion 56 is provided between the quantum well layer 54 and the first semiconductor portion 70. The third semiconductor portion 56 is provided between the first semiconductor portion 70 and the second semiconductor portion 52. The third semiconductor portion 56 is a semiconductor layer having the first conductivity type. The first conductivity type is, for example, n-type. The third semiconductor portion 56 is, for example, an n-type GaN layer doped with Si.

A first columnar portion 50a of the plurality of columnar portions 50 is the columnar portion 50 provided between the first electrode 30 and the first semiconductor portion 70. The first electrode 30 is provided between the first columnar portion 50a and the substrate 10. The first electrode 30 is electrically coupled to the second semiconductor portion 52 of the first columnar portion 50a. In the illustrated example, the first electrode 30 is in contact with the second semiconductor portion 52 of the first columnar portion 50a. The second semiconductor portion 52 of the first columnar portion 50a may be in ohmic contact with the first electrode 30.

A second columnar portion 50b of the plurality of columnar portions 50 is the columnar portion 50 provided between the second electrode 40 and the first semiconductor portion 70. The second electrode 40 is provided between the second columnar portion 50b and the substrate 10. In the example illustrated, the second columnar portion 50b is in contact with the second electrode 40. The second semiconductor portion 52 of the second columnar portion 50b may be in ohmic contact with the second electrode 40. In the illustrated example, the second columnar portion 50b is in contact with the conductive member 60.

A third columnar portion 50c of the plurality of columnar portions 50 is the columnar portion 50 separated from the first electrode 30 and the conductive member 60. In the illustrated example, the third columnar portion 50c is provided between the first columnar portion 50a and the second columnar portion 50b. That is, the third columnar portion 50c is not electrically coupled to the first electrode 30 and the second electrode 40 on the circuit substrate 12 side.

A plurality of the first columnar portions 50a are provided. In the illustrated example, a gap is formed between the adjacent first columnar portions 50a. A plurality the of second columnar portions 50b are provided. The conductive member 60 is provided between the adjacent second columnar portions 50b. The number of the first columnar portions 50a is, for example, greater than or equal to the number of the second columnar portions 50b. The number of first columnar portions 50a is, for example, greater than the number of second columnar portions 50b. A plurality of the third columnar portions 50c are provided. In the illustrated example, a gap is provided between the third columnar portions 50c adjacent to each other. There is a gap between the first columnar portion 50a and the third columnar portion 50c adjacent to each other. The plurality of first columnar portions 50a, the plurality of second columnar portions 50b, and the plurality of third columnar portions 50c are provided, for example, at the same pitch. The diameters of the first columnar portion 50a, the second columnar portion 50b, and the third columnar portion 50c are, for example, the same as each other.

A height H3 of the first columnar portion 50a and a height H4 of the second columnar portion 50b are, for example, the same. In the illustrated example, a distance between the lower surface of the first columnar portion 50a and the first semiconductor portion 70 is the same as a distance between the lower surface of the second columnar portion 50b and the first semiconductor portion 70. The “lower surfaces of the columnar portions 50a, 50b” are surfaces on the substrate 10 side of the columnar portions 50a, 50b, respectively.

The quantum well layer 54 of the first columnar portion 50a is a light-emitting layer that generates light when a current is injected. The second semiconductor portion 52 and the third semiconductor portion 56 of the first columnar portion 50a are cladding layers having a function of confining light in the quantum well layer 54 of the first columnar portion 50a. The quantum well layer 54 of the second columnar portion 50b does not generate light. The quantum well layer 54 of the third columnar portion 50c does not generate light. In the illustrated example, the quantum well layers 54 of the columnar portions 50 other than the first columnar portion 50a among the plurality of columnar portions 50 do not generate light.

In the light-emitting device 100, a pin diode is configured by the p-type second semiconductor portion 52 of the first columnar portion 50a, the i-type quantum well layer 54 of the first columnar portion 50a, and the n-type third semiconductor portion 56 of the first columnar portion 50a. In the light-emitting device 100, when a forward bias voltage of the pin diode is applied between the first electrode 30 and the second electrode 40, a current is injected into the quantum well layer 54 of the first columnar portion 50a, and electrons and holes are recombined in the quantum well layer 54. This recombination causes light emission. The light generated in the quantum well layer 54 of the first columnar portion 50a propagates in the in-plane direction, forms a standing wave by the effect of the photonic crystal by the plurality of first columnar portions 50a, and receives a gain in the quantum well layer 54 of the first columnar portion 50a to cause laser oscillation. The light-emitting device 100 emits the +1st order diffracted light and the −1st order diffracted light as laser light in the stacking direction.

The light generated in the quantum well layer 54 of the first columnar portion 50a and traveling toward the first electrode 30 is reflected by the first electrode 30. Thereby, the light-emitting device 100 can emit light only from the first semiconductor portion 70 side.

The first columnar portion 50a and the third columnar portion 50c are adjacent to each other. The pitch between the first columnar portion 50a and the third columnar portion 50c adjacent to each other is the same as the pitch between the first columnar portions 50a adjacent to each other. Therefore, for example, compared to a case where the first columnar portion and the second columnar portion are adjacent to each other, it is possible to increase the period of the refractive index difference felt by the light propagating in the in-plane direction. The refractive index difference is a difference between a refractive index of the columnar portion 50 and a refractive index of the gap between the adjacent columnar portions 50. When the conductive member is present between the adjacent columnar portions, the refractive index difference is changed, the periodicity is broken, the light generated from the vicinity of the first columnar portion adjacent to the third columnar portion cannot obtain the effect of the photonic crystal, and the light extraction efficiency is reduced.

The conductive member 60 is provided at the second electrode 40. The conductive member 60 is provided between the second electrode 40 and the first semiconductor portion 70. The conductive member 60 electrically couples the second electrode 40 and the first semiconductor portion 70. In the illustrated example, the conductive member 60 is in contact with the second metal layer 46 and the first semiconductor portion 70. The conductive member 60 is separated from the first columnar portion 50a.

The conductive member 60 is provided between the adjacent second columnar portions 50b. The conductive member 60 surrounds the second columnar portion 50b when viewed in the stacking direction. The conductive member 60 is provided at a side surface 51 of the second columnar portion 50b. The side surface 51 is formed of, for example, an m-plane.

The material of the conductive member 60 is, for example, platinum. The conductive member 60 is, for example, provided integrally with the second metal layer 46. By integrally providing the second metal layer 46 and the conductive member 60, the second metal layer 46 and the conductive member 60 can be formed in the same step. Thus, the manufacturing process can be shortened as compared with the case where the second metal layer 46 and the conductive member 60 are formed in separate steps. The material of the second metal layer 46 and the material of the conductive member 60 may be different from each other. Further, the material constituting the first metal layer 44 and the material constituting the conductive member 60 may be different or the same.

The first semiconductor portion 70 is provided at the plurality of columnar portions 50. In the illustrated example, the first semiconductor portion 70 is in contact with the plurality of columnar portions 50 and the conductive member 60. The first semiconductor portion 70 is a semiconductor layer having the first conductivity type. The first semiconductor portion 70 is, for example, an n-type GaN layer doped with Si. The second electrode 40 is electrically coupled to, via the conductive member 60 and the first semiconductor portion 70, the third semiconductor portion 56 of the first columnar portion 50a.

Although not illustrated, a mask layer for growing the columnar portion 50 may be provided under the first semiconductor portion 70. The mask layer is, for example, a titanium layer, a silicon oxide layer, a titanium oxide layer, or an aluminum oxide layer.

In the above description, the InGaN-based quantum well layer 54 has been described. However, as the quantum well layer 54 of the first columnar portion 50a, various material systems capable of emitting light when a current is injected can be used according to wavelengths of light to be emitted. For example, a semiconductor material such as an AlGaN-based material, an AlInN-based material, or an AlGaInN-based material can be used.

The light-emitting device 100 is not limited to a laser, and may be a light-emitting diode (LED).

Although an example in which the first conductivity type is n-type and the second conductivity type is p-type has been described above, the first conductivity type may be p-type and the second conductivity type may be n-type.

The light-emitting device 100 has, for example, the following advantageous effects.

The light-emitting device 100 includes the substrate 10, the first columnar portion 50a and the second columnar portion 50b each including the first semiconductor portion 70 having the first conductivity type, the second semiconductor portion 52 having the second conductivity type different from the first conductivity type, the third semiconductor portion 56 having the first conductivity type and provided between the first semiconductor portion 70 and the second semiconductor portion 52, and the quantum well layer 54 provided between the second semiconductor portion 52 and the third semiconductor portion 56, the first electrode 30 provided between the first columnar portion 50a and the substrate 10, the second electrode 40 provided between the second columnar portion 50b and the substrate 10, and the conductive member 60 that electrically couples the second electrode 40 and the first semiconductor portion 70. The first columnar portion 50a and the second columnar portion 50b each protrude from the first semiconductor portion 70 toward the substrate 10 side. The second semiconductor portion 52 is provided between the substrate 10 and the quantum well layer 54. The first electrode 30 is electrically coupled to the second semiconductor portion 52 of the first columnar portion 50a, and the second electrode 40 is electrically coupled to, via the conductive member 60 and the first semiconductor portion 70, the third semiconductor portion 56 of the first columnar portion 50a.

Therefore, in the light-emitting device 100, it is possible to reduce the difference between the position of the first surface 32 of the first electrode 30 on the side opposite to the first semiconductor portion 70 and the position of the second surface 42 of the second electrode 40 on the side opposite to the first semiconductor portion 70 in the stacking direction, compared to a case where the second columnar portion is not provided. Therefore, in the light-emitting device 100, the light-emitting element 20 can be easily flip-chip mounted on the substrate 10. In particular, in the light-emitting device 100, both the first columnar portion 50a and the second columnar portion 50b include the second semiconductor portion 52, the quantum well layer 54, and the third semiconductor portion 56, thereby it is easy to make the height H3 of the first columnar portion 50a and the height H4 of the second columnar portion 50b equal to each other.

In the light-emitting device 100, the height H3 of the first columnar portion 50a and the height H4 of the second columnar portion 50b are the same. Therefore, in the light-emitting device 100, the difference between the position of the first surface 32 of the first electrode 30 and the position of the second surface 42 of the second electrode 40 in the stacking direction can be reduced as compared with the case where the height H3 and the height H4 are different from each other.

In the light-emitting device 100, the material of the conductive member 60 is platinum. Therefore, in the light-emitting device 100, the conductive member 60 can be formed by an atomic layer deposition (ALD) method. Thereby, for example, even if the interval between the adjacent second columnar portions 50b is narrow, the conductive member 60 can be formed between the adjacent second columnar portions 50b.

In the light-emitting device 100, the height H1 of the first electrode 30 and the height H2 of the second electrode 40 are the same. Therefore, in the light-emitting device 100, the difference between the position of the first surface 32 of the first electrode 30 and the position of the second surface 42 of the second electrode 40 in the stacking direction can be reduced as compared with the case where the height H1 and the height H2 are different from each other.

In the light-emitting device 100, the number of first columnar portions 50a is greater than or equal to the number of second columnar portions 50b. Therefore, in the light-emitting device 100, the intensity of the emitted light can be increased as compared with the case where the number of the first columnar portions is smaller than the number of the second columnar portions.

1.2. Manufacturing Method of Light-Emitting Device

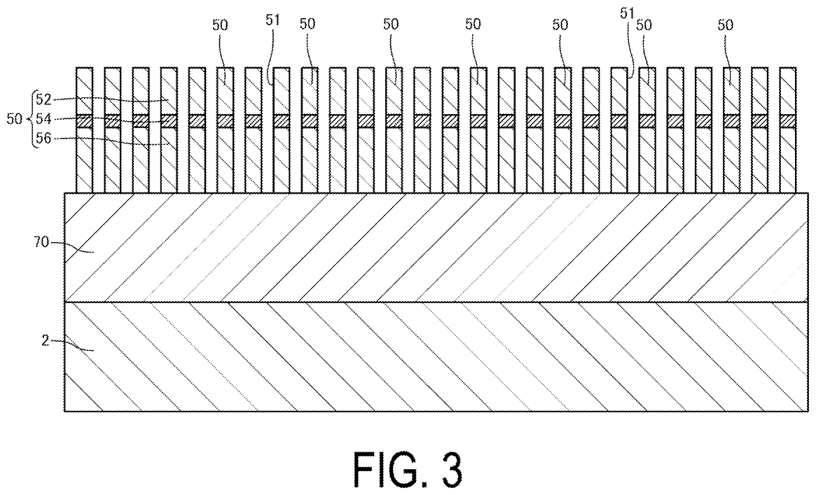

Next, a manufacturing method of the light-emitting device 100 according to the first exemplary embodiment will be described with reference to the drawings. FIGS. 3 to 9 are cross-sectional views schematically illustrating the manufacturing process of the light-emitting device 100 according to the first exemplary embodiment. For convenience, FIGS. 3 to 9 are illustrated upside down with respect to FIG. 1.

As illustrated in FIG. 3, the first semiconductor portion 70 is crystal-grown on a growth substrate 2. Examples of the crystal growth method include a metal organic chemical vapor deposition (MOCVD) method and a molecular beam epitaxy (MBE) method. The growth substrate 2 is, for example, a sapphire substrate, a Si substrate, a GaN substrate, or a SiC substrate.

In “1.2. Manufacturing Method of Light-emitting Device”, in the stacking direction, the direction from the quantum well layer 54 toward the second semiconductor portion 52 is described as “up”, and the direction from the quantum well layer 54 toward the third semiconductor portion 56 is described as “down”. The same applies to “2.2. Manufacturing Method of Light-emitting Device” described below.

Next, a mask layer (not illustrated) is formed at the first semiconductor portion 70. The mask layer is formed by, for example, an electron beam evaporation method, an ALD method, or a sputtering method.

Next, a resist is applied on the mask layer, patterning is performed by electron beam (EB) drawing or photolithography, the mask layer is etched using the resist as a mask, the first semiconductor portion 70 is exposed, and the resist is removed. Then, the third semiconductor portion 56, the quantum well layer 54, and the second semiconductor portion 52 are epitaxially grown in this order on the first semiconductor portion 70 using the mask layer as a mask. Examples of the method for epitaxial growth include the MOCVD and MBE. By this step, the plurality of columnar portions 50 can be formed.

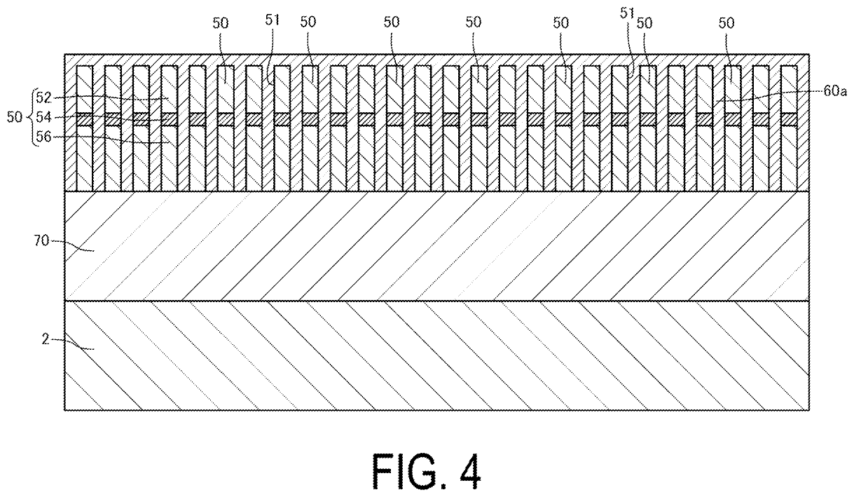

As illustrated in FIG. 4, a conductive member 60a is formed at the upper surface and the side surface 51 of the columnar portion 50. The conductive member 60a is formed by, for example, an ALD method. The conductive member 60a is formed to fill a space between the adjacent columnar portions 50. The conductive member 60a is also formed above between the adjacent columnar portions 50.

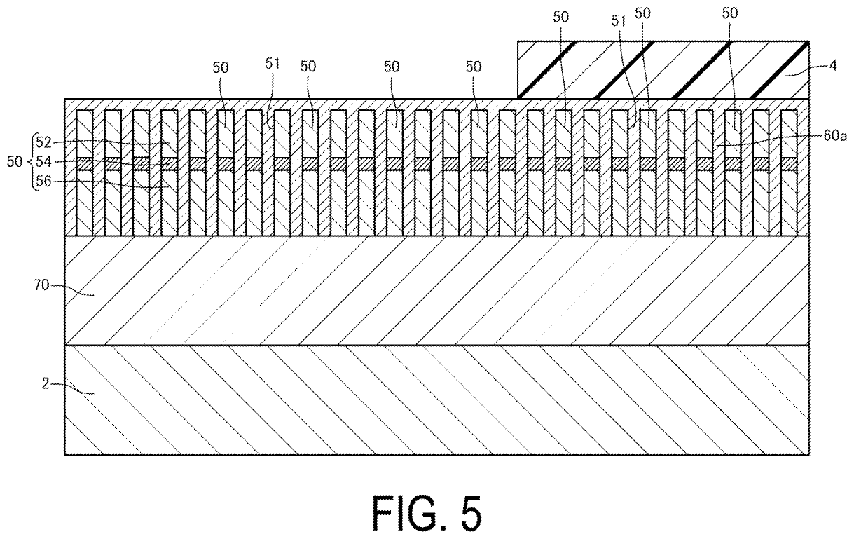

As illustrated in FIG. 5, a resist layer 4 having a predetermined shape is formed at the conductive member 60a. The resist layer 4 is formed by, for example, application by spin coating and photolithography.

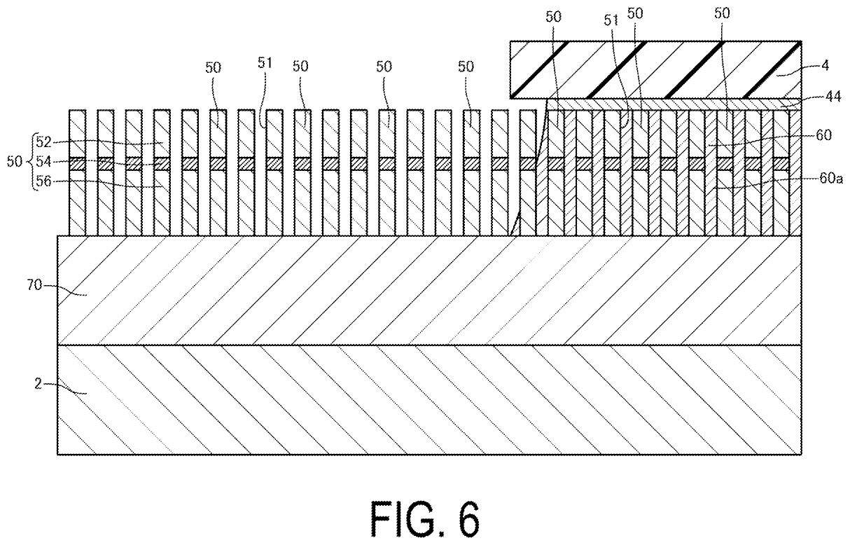

As illustrated in FIG. 6, the conductive member 60a is etched using the resist layer 4 as a mask. As the etching, wet etching is used. As a result, etching damage to the columnar portion 50 can be reduced and the conductive member 60a can be removed as compared with the case of using dry etching. By this step, the conductive member 60 made of the conductive member 60a can be formed between the adjacent columnar portions 50. Further, the first metal layer 44 made of the conductive member 60a can be formed at the upper surface of the columnar portion 50 and above the space between the adjacent columnar portions 50. By this step, a portion of the first semiconductor portion 70 is exposed.

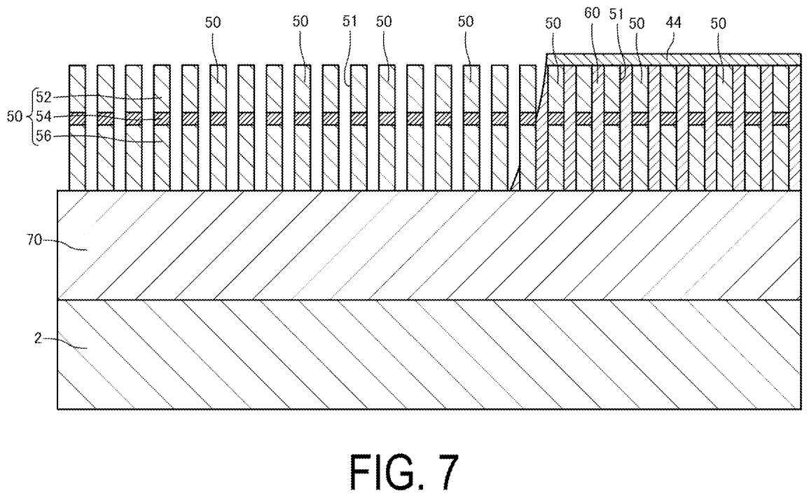

As illustrated in FIG. 7, the resist layer 4 is removed. The peeling of the resist layer 4 is performed by, for example, organic peeling or O₂ plasma.

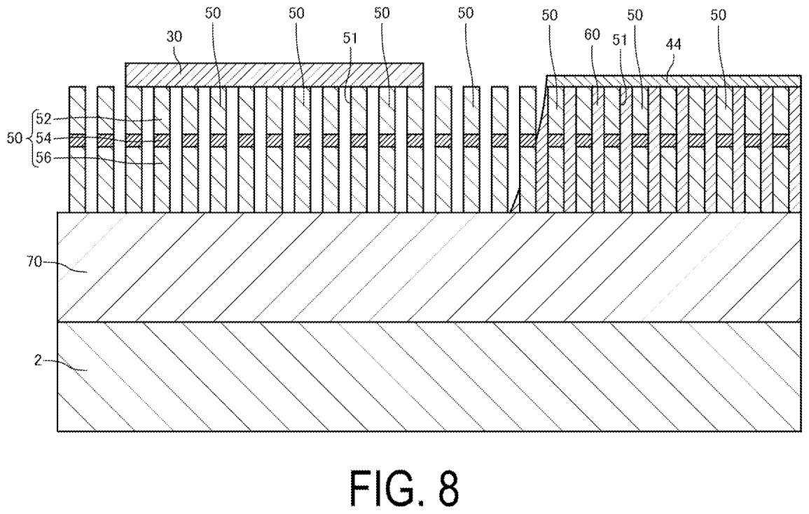

As illustrated in FIG. 8, the first electrode 30 is formed at the columnar portion 50. The first electrode 30 is formed by film formation by a vacuum deposition method or a sputtering method, and patterning. The patterning is performed by, for example, photolithography and etching. The first electrode 30 may be formed by a lift-off method.

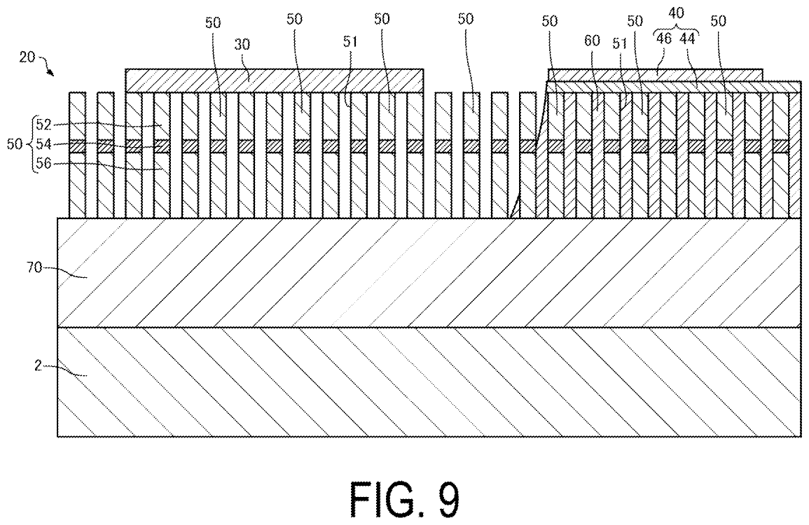

As illustrated in FIG. 9, the second metal layer 46 is formed at the first metal layer 44. The second metal layer 46 is formed by, for example, the same method as that of the first electrode 30. By this step, the second electrode 40 including the first metal layer 44 and the second metal layer 46 can be formed. Further, the light-emitting element 20 including the growth substrate 2, the first electrode 30, the second electrode 40, the columnar portion 50, and the first semiconductor portion 70 can be formed.

Next, the growth substrate 2 is removed from the first semiconductor portion 70. The growth substrate 2 is removed by, for example, chemical mechanical polishing (CMP). When the growing substrate 2 has a high light-transmitting property with respect to the light generated in the quantum well layer 54 of the first columnar portion 50a, the growing substrate 2 may not be removed.

As illustrated in FIG. 1, the first electrode 30 is bonded to the first bump 14, the second electrode 40 is bonded to the second bump 16, and the light-emitting element 20 is flip-chip mounted on the substrate 10. In the stacking direction, for example, since the position of the first surface 32 of the first electrode 30 and the position of the second surface 42 of the second electrode 40 are the same, the light-emitting element 20 can be easily flip-chip mounted. The bumps 14, 16 are formed by, for example, a plating method.

Through the above steps, the light-emitting device 100 can be manufactured.

### 2. Second Exemplary Embodiment

### 2.1. Light-Emitting Device

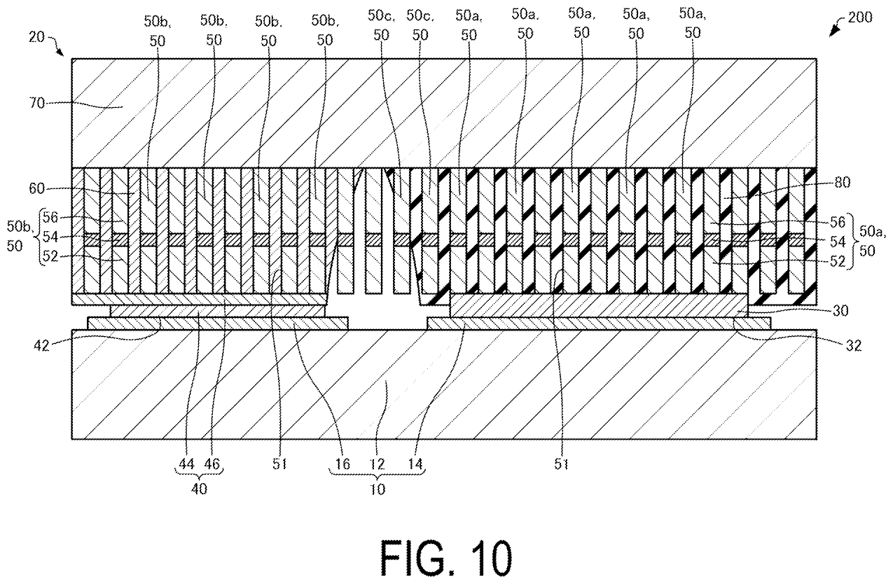

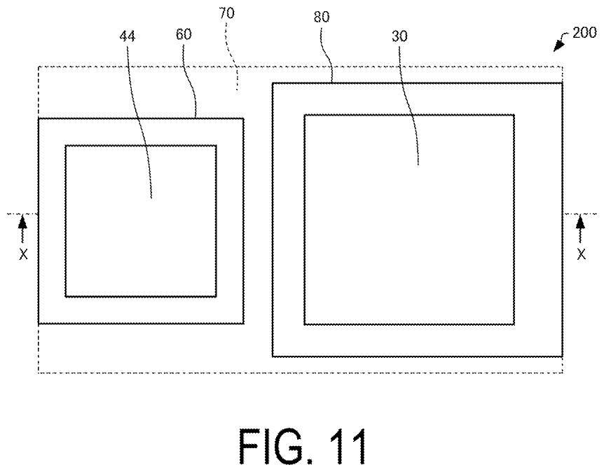

Next, a light-emitting device according to a second exemplary embodiment will be described with reference to the drawings. FIG. 10 is a cross-sectional view schematically illustrating a light-emitting device 200 according to the second exemplary embodiment. FIG. 11 is a plan view schematically illustrating the light-emitting device 200 according to the second exemplary embodiment. FIG. 10 is a cross-sectional view taken along line X-X in FIG. 11.

Hereinafter, in the light-emitting device 200 according to the second exemplary embodiment, members having the same functions as those of the constituent members of the light-emitting device 100 according to the first exemplary embodiment described above are denoted by the same reference numerals, and a detailed description thereof will be omitted.

As illustrated in FIGS. 10 and 11, the light-emitting device 200 is different from the above-described light-emitting device 100 in that an insulating layer 80 is provided. For the sake of convenience, members other than the first electrode 30, the first metal layer 44, the conductive member 60, the first semiconductor portion 70, and the insulating layer 80 are not illustrated in FIG. 11. In FIG. 11, an outer edge of the conductive member 60 and the insulating layer 80 is illustrated. In FIG. 11, the first semiconductor portion 70 is illustrated in a see-through manner.

The light-emitting element 20 includes the insulating layer 80. The insulating layer 80 is provided between the first electrode 30 and the first semiconductor portion 70. The insulating layer 80 covers the side surface 51 of the first columnar portion 50a. The insulating layer 80 is provided between the adjacent first columnar portions 50a. The insulating layer 80 surrounds the first columnar portion 50a when viewed from the stacking direction. The insulating layer 80 is separated from the conductive member 60.

The insulating layer 80 is, for example, an aluminum oxide (Al₂O₃) layer or a silicon oxide (SiO₂) layer. When the light generated in the quantum well layer 54 of the first columnar portion 50a propagates in the in-plane direction due to the photonic-crystal effect, the light propagates through the insulating layer 80 in the in-plane direction.

The light-emitting device 200 includes the insulating layer 80 that covers the side surface 51 of the first columnar portion 50a. Therefore, in the light-emitting device 200, the first columnar portion 50a can be protected by the insulating layer 80.

Further, in the light-emitting device 200, since the insulating layer 80 is provided between the adjacent first columnar portions 50a, it is possible to increase the interval between the adjacent first columnar portions 50a compared to a case where the insulating layer is not provided between the adjacent first columnar portions. For example, in a case where the insulating layer is not provided between the adjacent first columnar portions, when the interval between the adjacent first columnar portions is greater than or equal to 30 nm, the material of the electrodes formed by the sputtering method or the vacuum evaporation method adheres to the quantum well layer side rather than the second semiconductor portion, and a short-circuit failure occurs.

### 2.2. Manufacturing Method of Light-Emitting Device

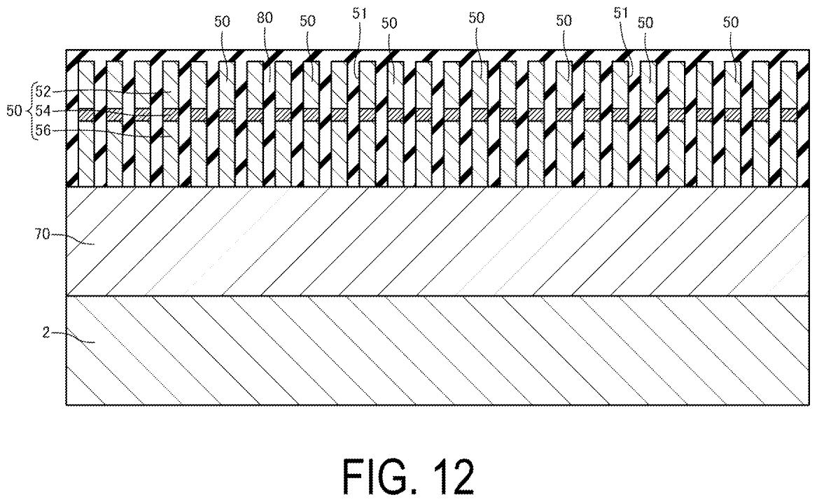

Next, a manufacturing method of the light-emitting device 200 according to the second exemplary embodiment will be described with reference to the drawings. FIGS. 12 to 24 are cross-sectional views schematically illustrating the manufacturing process of the light-emitting device 200 according to the second exemplary embodiment. For convenience, FIGS. 12 to 24 are illustrated upside down with respect to FIG. 10.

As illustrated in FIG. 3, the manufacturing method of the light-emitting device 200 is the same as the manufacturing method of the light-emitting device 100 described above until the plurality of columnar portions 50 are formed at the first semiconductor portion 70.

Next, as illustrated in FIG. 12, the insulating layer 80 is formed at the upper surface and the side surface 51 of the columnar portion 50. The insulating layer 80 is formed by, for example, an ALD method. The insulating layer 80 is formed to fill the space between the adjacent columnar portions 50. The insulating layer 80 is also formed above between the adjacent columnar portions 50.

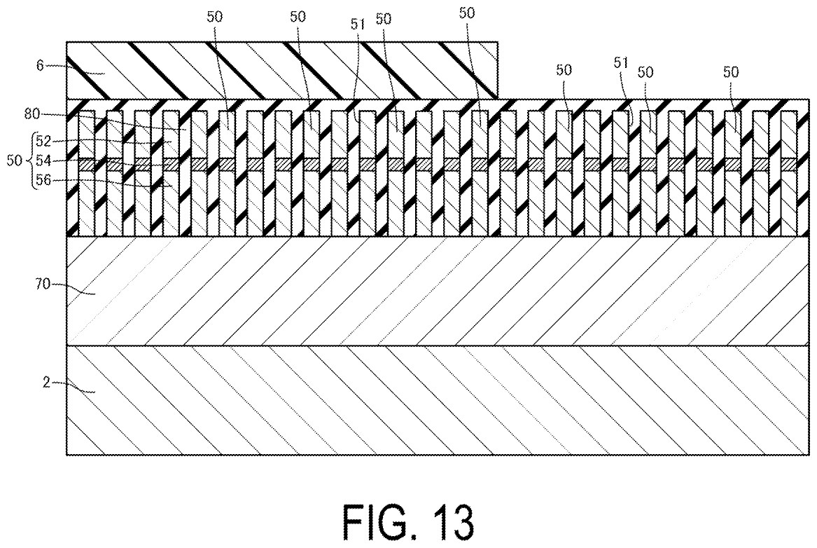

As illustrated in FIG. 13, a resist layer 6 having a predetermined shape is formed at the insulating layer 80. The resist layer 6 is formed by, for example, application by spin coating and photolithography.

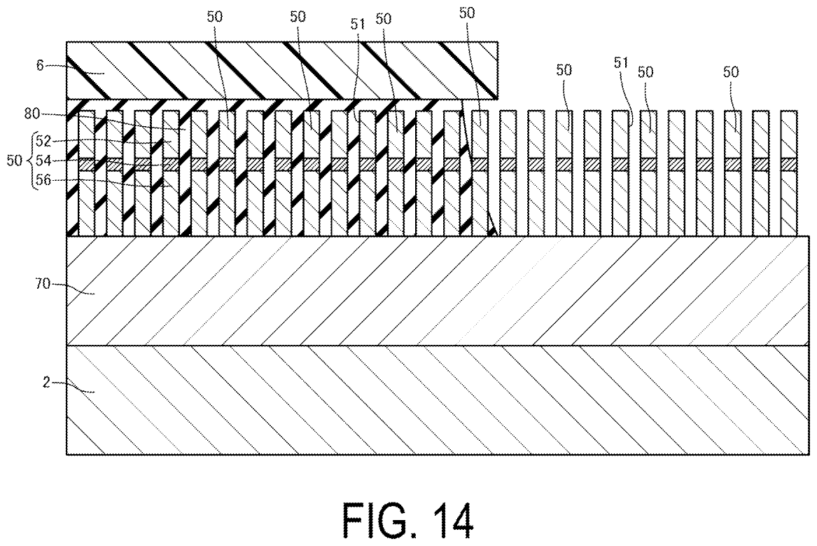

As illustrated in FIG. 14, the insulating layer 80 is etched using the resist layer 6 as a mask. As the etching, wet etching is used. Thus, the etching amount of the columnar portion 50 can be reduced as compared with the case of using dry etching. By this step, a portion of the first semiconductor portion 70 is exposed. As the etching liquid, for example, a dilute hydrofluoric acid-based liquid or a buffered hydrofluoric acid-based liquid is used.

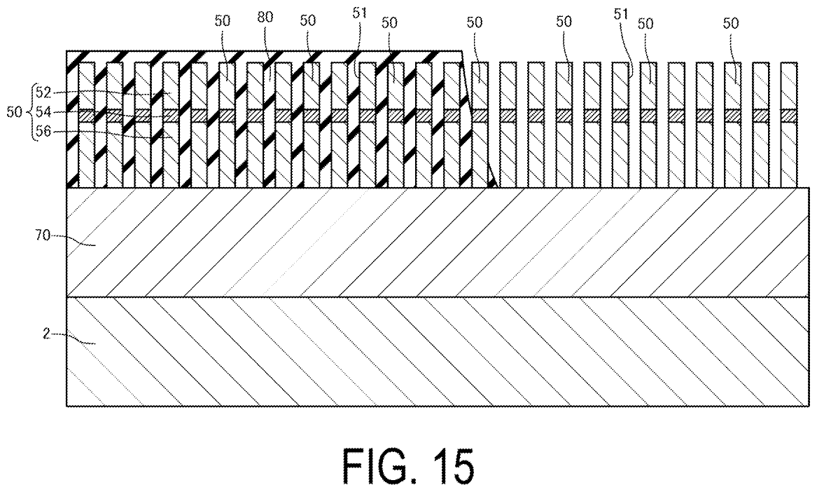

As illustrated in FIG. 15, the resist layer 6 is removed. The peeling of the resist layer 6 is performed by, for example, an organic peeling method.

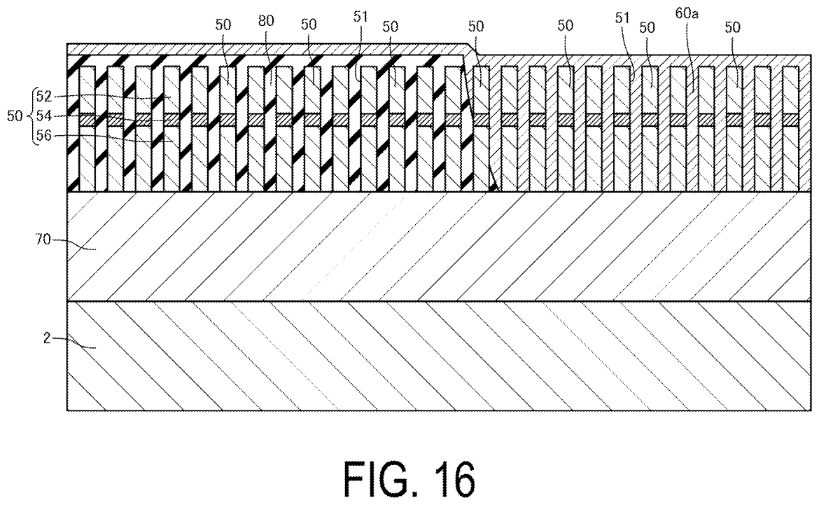

As illustrated in FIG. 16, the conductive member 60a is formed at the upper surface and the side surface 51 of the columnar portion 50 and at the upper surface and the side surface of the insulating layer 80. The method of forming the conductive member 60a is the same as that of the light-emitting device 100.

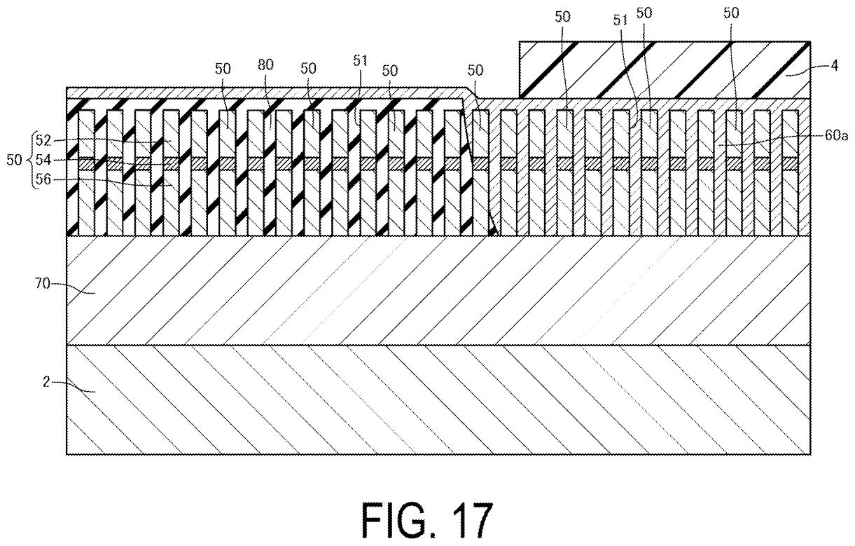

As illustrated in FIG. 17, the resist layer 4 having a predetermined shape is formed at the conductive member 60a. The method of forming the resist layer 4 is the same as that of the light-emitting device 100.

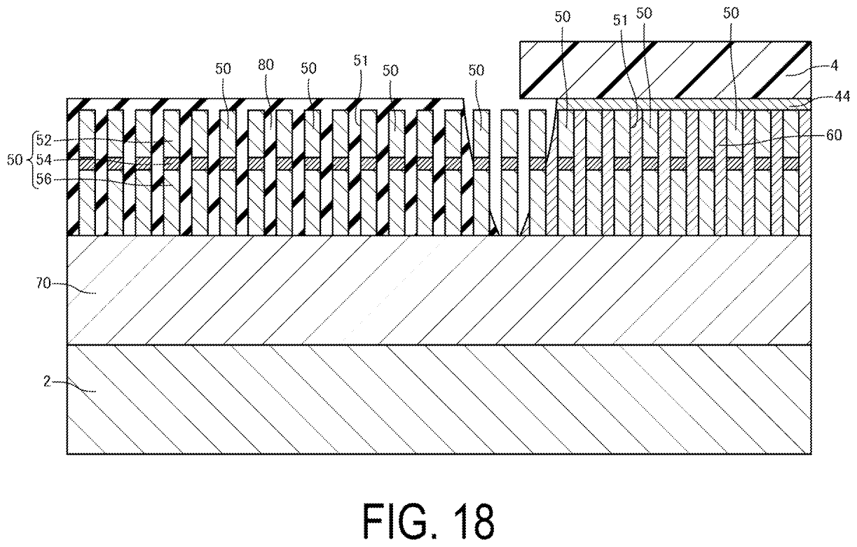

As illustrated in FIG. 18, the conductive member 60a is etched using the resist layer 4 as a mask. The method of etching the conductive member 60a is the same as that of the light-emitting device 100. By this step, the insulating layer 80 is exposed.

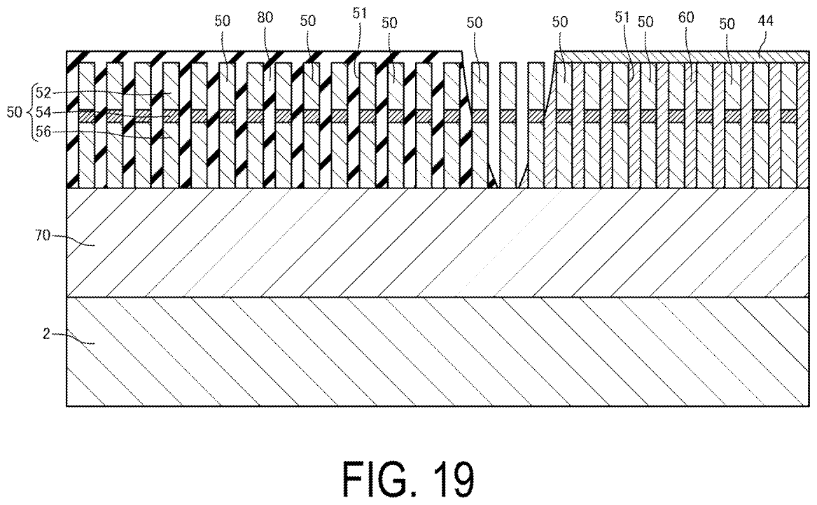

As illustrated in FIG. 19, the resist layer 4 is removed. The method for removing the resist layer 4 is the same as that of the light-emitting device 100.

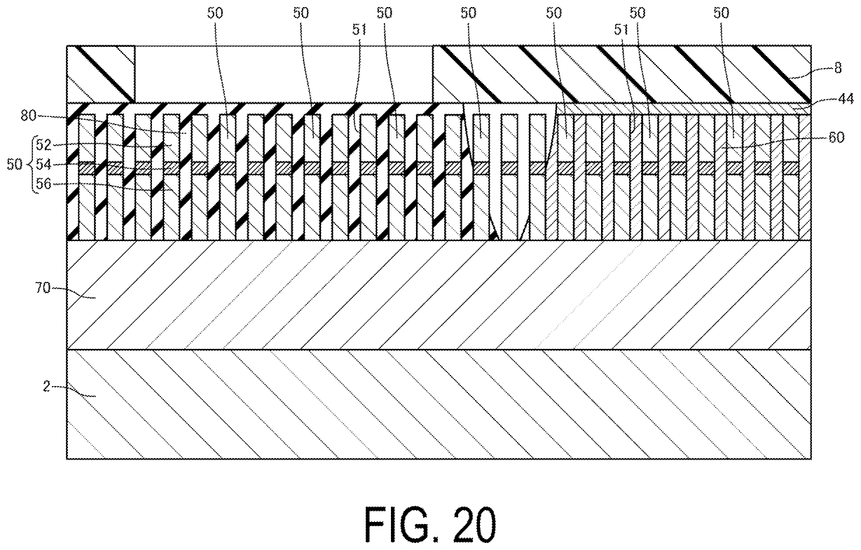

As illustrated in FIG. 20, a resist layer 8 having a predetermined shape is formed at the first metal layer 44 and the insulating layer 80. The resist layer 8 is formed by, for example, application by spin coating and photolithography.

As illustrated in FIG. 21, the insulating layer 80 is etched using the resist layer 8 as a mask. As the etching, wet etching is used. As a result, etching damage to the columnar portion 50 can be reduced and the insulating layer 80 can be etched as compared with the case of using dry etching. As the etching liquid, for example, a dilute hydrofluoric acid-based liquid or a buffered hydrofluoric acid-based liquid is used. By this step, some of the plurality of columnar portions 50 are exposed.

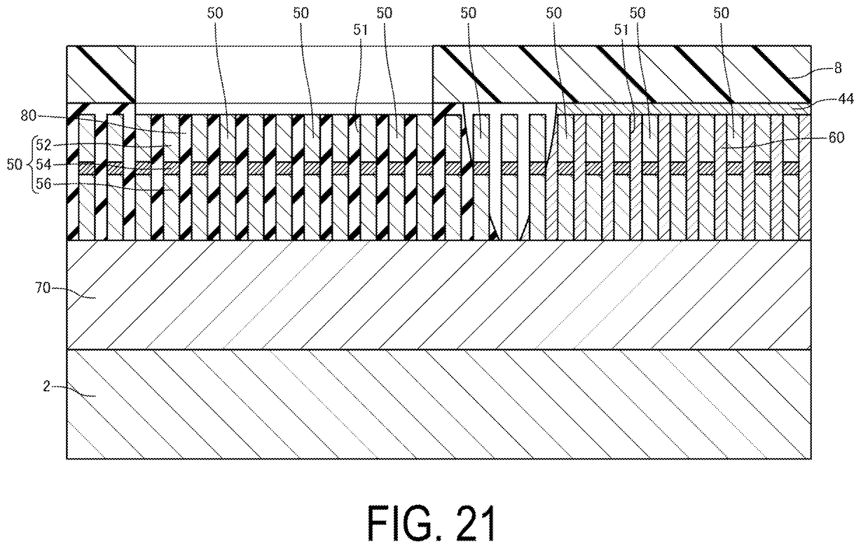

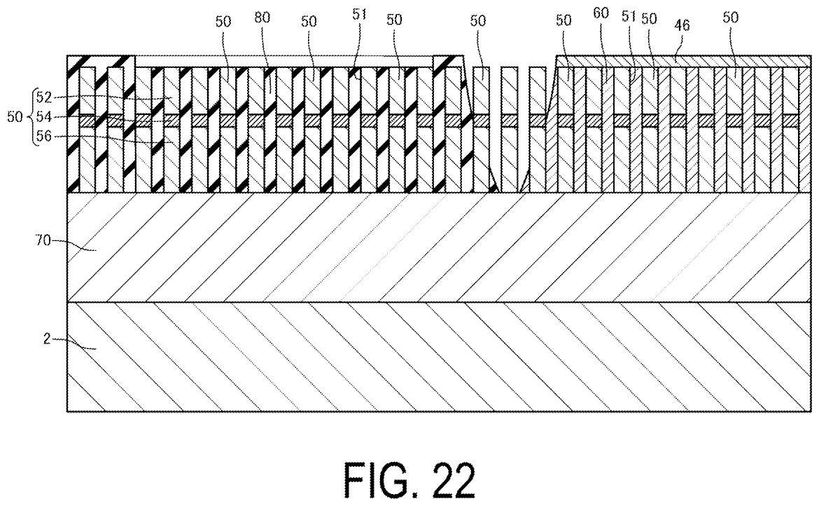

As illustrated in FIG. 22, the resist layer 8 is removed. The peeling of the resist layer 8 is performed by, for example, an organic peeling method.

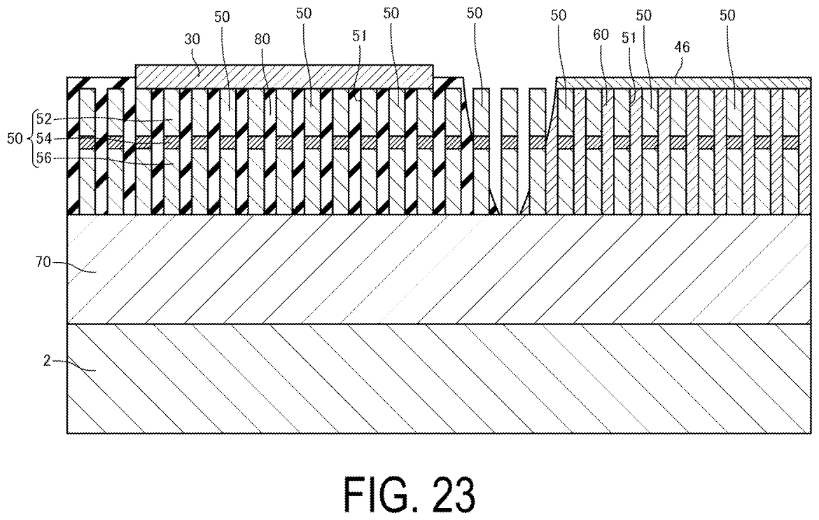

As illustrated in FIG. 23, the first electrode 30 is formed at the insulating layer 80 and the exposed columnar portion 50. The method of forming the first electrode 30 is the same as that of the light-emitting device 100.

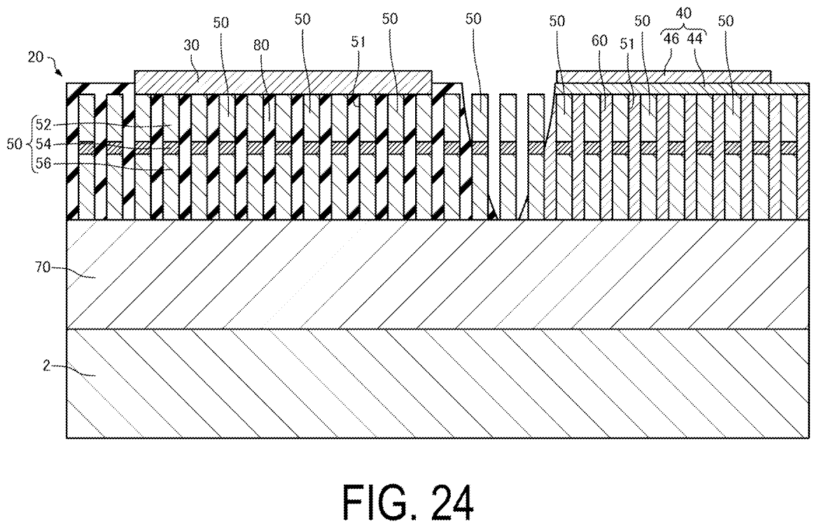

As illustrated in FIG. 24, the second metal layer 46 is formed at the conductive member 60. The method of forming the second metal layer 46 is the same as that of the light-emitting device 100.

As illustrated in FIG. 10, the first electrode 30 is bonded to the first bump 14, the second electrode 40 is bonded to the second bump 16, and the light-emitting element 20 is flip-chip mounted on the substrate 10.

Through the above steps, the light-emitting device 200 can be manufactured.

### 3. Third Exemplary Embodiment

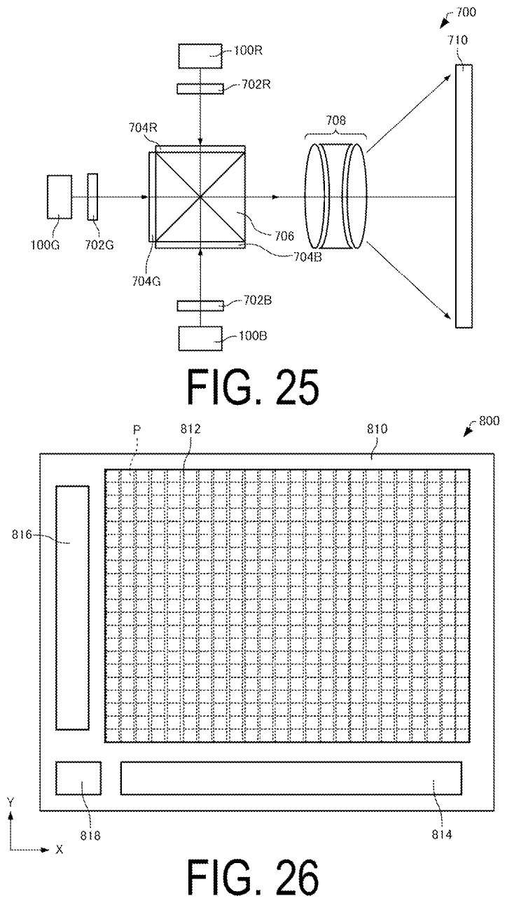

Next, a projector according to a third exemplary embodiment will be described with reference to the drawings. FIG. 25 is a diagram schematically illustrating a projector 700 according to the third exemplary embodiment.

The projector 700 includes, for example, the light-emitting device 100 as a light source.

The projector 700 includes a housing (not illustrated) and a red light source 100R, a green light source 100G, and a blue light source 100B that are provided in the housing and emit red, green, and blue light, respectively. In FIG. 25, the red light source 100R, the green light source 100G, and the blue light source 100B are simplified for the sake of simplicity.

The projector 700 further includes a first optical element 702R, a second optical element 702G, a third optical element 702B, a first light modulation device 704R, a second light modulation device 704G, a third light modulation device 704B, and a projection device 708, which are provided in the housing. The first light modulation device 704R, the second light modulation device 704G, and the third light modulation device 704B are, for example, transmissive liquid crystal light valves. The projection device 708 is, for example, a projection lens.

The light emitted from the red light source 100R enters the first optical element 702R. The light emitted from the red light source 100R is collected by the first optical element 702R. Note that the first optical element 702R may have a function other than light collection. The same applies to the second optical element 702G and the third optical element 702B which will be described below.

The light collected by the first optical element 702R enters the first light modulation device 704R. The first light modulation device 704R modulates the incident light according to image information. The projection device 708 enlarges the image formed by the first light modulation device 704R and projects the enlarged image onto a screen 710.

The light emitted from the green light source 100G enters the second optical element 702G. The light emitted from the green light source 100G is collected by the second optical element 702G.

The light collected by the second optical element 702G enters the second light modulation device 704G. The second light modulation device 704G modulates the incident light in accordance with image information. The projection device 708 enlarges the image formed by the second light modulation device 704G and projects the enlarged image onto the screen 710.

The light emitted from the blue light source 100B enters the third optical element 702B. The light emitted from the blue light source 100B is collected by the third optical element 702B.

The light collected by the third optical element 702B enters the third light modulation device 704B. The third light modulation device 704B modulates the incident light in accordance with image information. The projection device 708 enlarges the image formed by the third light modulation device 704B and projects the enlarged image onto the screen 710.

The projector 700 further includes a cross dichroic prism 706 that combines the light beams emitted from the first light modulation device 704R, the second light modulation device 704G, and the third light modulation device 704B and guides the combined light beam to the projection device 708.

The three color lights modulated by the first light modulation device 704R, the second light modulation device 704G, and the third light modulation device 704B enter the cross dichroic prism 706. The cross dichroic prism 706 is formed by bonding four rectangular prisms together, and a dielectric multilayer film that reflects red light and a dielectric multilayer film that reflects blue light are disposed on the inner surface of the cross dichroic prism. The three color lights are combined by these dielectric multilayer films to form light representing a color image. Then, the combined light is projected on the screen 710 by the projection device 708, and an enlarged image is displayed.

By controlling the light-emitting device 100 as a pixel of the image in accordance with image information, the red light source 100R, the green light source 100G, and the blue light source 100B may directly form an image without using the first light modulation device 704R, the second light modulation device 704G, and the third light modulation device 704B. The projection device 708 may enlarge the image formed by the red light source 100R, the green light source 100G, and the blue light source 100B and project the enlarged image onto the screen 710.

In the above-described example, a transmissive liquid crystal light valve is used as the light modulation device, but a light valve other than a liquid crystal light valve may be used, or a reflective light valve may be used. Examples of such a light valve include a reflective liquid crystal light valve and a digital micro mirror device. Further, the configuration of the projection device is appropriately changed depending on the type of the light valve to be used.

Further, the present disclosure can also be applied to a light source device of a scanning type image display device including a scanning unit which is an image forming device for displaying an image of a desired size on a display surface by scanning light from a light source on a screen.

### 4. Fourth Exemplary Embodiment

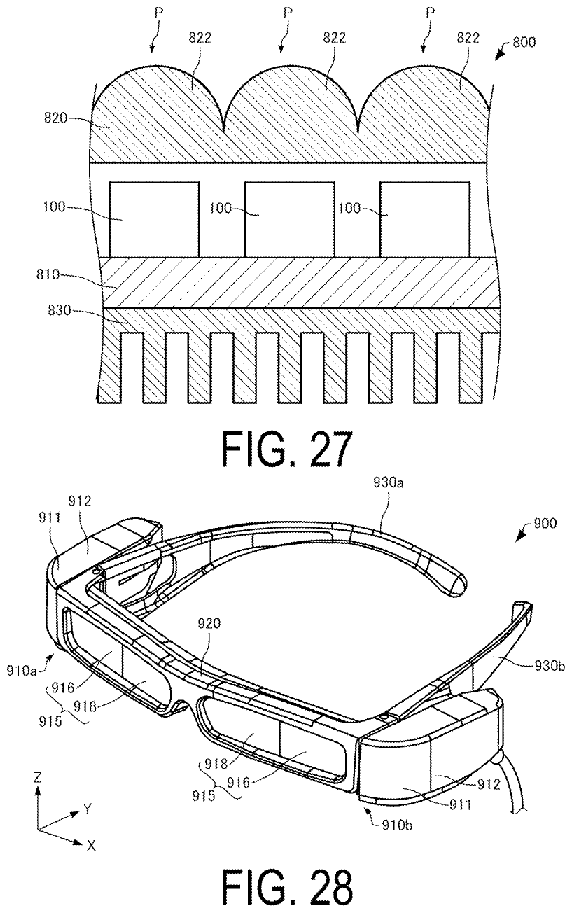

Next, a display according to a fourth exemplary embodiment will be described with reference to the drawings. FIG. 26 is a plan view schematically illustrating a display 800 according to the present exemplary embodiment. FIG. 27 is a cross-sectional view schematically illustrating the display 800 according to the present exemplary embodiment. In FIG. 26, an X-axis and a Y-axis are illustrated as two axes orthogonal to each other.

The display 800 includes, for example, the light-emitting device 100 as a light source.

The display 800 is a display device that displays an image. The image includes an image that displays only character information. The display 800 is a self-emission type display. As illustrated in FIGS. 26 and 27, the display 800 includes, for example, a circuit board 810, a lens array 820, and a heat sink 830.

A drive circuit for driving the light-emitting device 100 is mounted on the circuit board 810. The drive circuit is, for example, a circuit including a complementary metal oxide semiconductor (CMOS). The drive circuit drives the light-emitting device 100 based on, for example, input image information. Although not illustrated, a light-transmissive substrate for protecting the circuit board 810 is disposed at the circuit board 810. The circuit board 810 may be formed of the circuit board 12 illustrated in FIG. 1.

The circuit board 810 includes, for example, a display region 812, a data line drive circuit 814, a scanning line drive circuit 816, and a control circuit 818.

The display region 812 is composed of a plurality of pixels P. In the illustrated example, the pixels P are arranged along the X-axis and the Y-axis.

Although not illustrated, the circuit board 810 is provided with a plurality of scanning lines and a plurality of data lines. For example, the scanning lines extend along the X-axis, and the data lines extend along the Y-axis. The scanning lines are coupled to the scanning line drive circuit 816. The data lines are coupled to the data line drive circuit 814. The pixels P are provided corresponding to intersections of the scanning lines and the data lines.

One pixel P includes, for example, one light-emitting device 100, one lens 822, and a pixel circuit (not illustrated). The pixel circuit includes a switching transistor functioning as a switch of the pixel P, a gate of the switching transistor is coupled to the scanning line, and one of a source and a drain of the switching transistor is coupled to the data line.

The data line drive circuit 814 and the scanning line drive circuit 816 are circuits for controlling the driving of the light-emitting device 100 constituting the pixel P. The control circuit 818 controls display of an image.

The control circuit 818 is supplied with image data from a host circuit. The control circuit 818 supplies various signals based on the image data to the data line drive circuit 814 and the scanning line drive circuit 816.

When the scanning line drive circuit 816 activates the scanning signal to select the scanning line, the switching transistor of the selected pixel P is turned on. At this time, the data line drive circuit 814 supplies a data signal from the data line to the selected pixel P, so that the light-emitting device 100 of the selected pixel P emits light according to the data signal.

The lens array 820 includes a plurality of lenses 822. For example, one lens 822 is provided for one light-emitting device 100. Light emitted from light-emitting device 100 enters one lens 822.

The heat sink 830 is in contact with the circuit board 810. The material of the heat sink 830 is, for example, a metal such as copper or aluminum. The heat sink 830 dissipates heat generated in the light-emitting device 100.

### 5. Fifth Exemplary Embodiment

### 5.1. Overall Configuration

Next, a head-mounted display according to a fifth exemplary embodiment will be described with reference to the drawings. FIG. 28 is a perspective view schematically illustrating a head-mounted display 900 according to the present exemplary embodiment. In FIG. 28, an X-axis, a Y-axis, and a Z-axis are illustrated as three axes orthogonal to each other.

As illustrated in FIG. 28, the head-mounted display 900 is a head-mounted display device having an appearance like glasses. The head-mounted display 900 is mounted on a head of a viewer. The viewer is a user who uses the head-mounted display 900. The head-mounted display 900 allows the viewer to visually recognize image light as a virtual image and visually recognize an external image in a see-through manner. The head-mounted display 900 can also be referred to as a virtual image display device.

The head-mounted display 900 includes, for example, a first display unit 910a, a second display unit 910b, a frame 920, a first temple 930a, and a second temple 930b.

The first display unit 910a and the second display unit 910b display images. To be specific, the first display unit 910a displays a right-eye virtual image of the viewer. The second display unit 910b displays a left-eye virtual image of the viewer. In the illustrated example, the first display unit 910a is provided in the −X-axis direction of the second display unit 910b. The display units 910a, 910b include, for example, an image forming device 911 and a light guide device 915.

The image forming device 911 forms image light. The image forming device 911 includes, for example, an optical system such as a light source and a projection device, and an external member 912. The external member 912 accommodates the light source and the projection device.

The light guide device 915 covers the front of the eyes of the viewer. The light guide device 915 guides the image light formed by the image forming device 911 and allows the viewer to visually recognize the external light and the image light in an overlapping manner. Details of the image forming device 911 and the light guide device 915 will be described below.

The frame 920 supports the first display unit 910a and the second display unit 910b. The frame 920 surrounds the display units 910a, 910b when viewed in the Y-axis direction, for example. In the illustrated example, the image forming device 911 of the first display unit 910a is attached to an end portion of the frame 920 in the −X-axis direction. The image forming device 911 of the second display unit 910b is attached to an end portion of the frame 920 in the +X-axis direction.

The first temple 930a and the second temple 930b extend from the frame 920. In the illustrated example, the first temple 930a extends in the +Y-axis direction from the end portion of the frame 920 in the −X-axis direction. The second temple 930b extends in the +Y-axis direction from the end portion of the frame 920 in the +X-axis direction.

The first temple 930a and the second temple 930b are suspended from the ears of the viewer when the head-mounted display 900 is worn by the viewer. The viewer's head is located between the temples 930a, 930b.

### 5.2. Image Forming Device and Light Guide Device

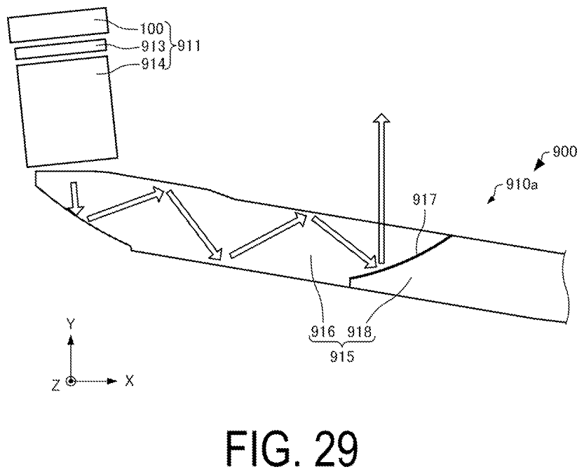

FIG. 29 is a diagram schematically illustrating the image forming device 911 and the light guide device 915 of the first display unit 910a of the head-mounted display 900 according to the exemplary embodiment. The first display unit 910a and the second display unit 910b have basically the same configuration. Therefore, the following description of the first display unit 910a can be applied to the second display unit 910b.

As illustrated in FIG. 29, the image forming device 911 includes, for example, the light-emitting device 100 as a light source, a light modulation device 913, and a projection device 914 for image formation.

The light modulation device 913 modulates light incident from the light-emitting device 100 in accordance with image information, and emits image light. The light modulation device 913 is a transmissive liquid crystal light valve. The light-emitting device 100 may be a self-emission type light-emitting device that emits light in accordance with input image information. In this case, the light modulation device 913 is not provided.

The projection device 914 projects the image light output from the light modulation device 913 toward the light guide device 915. The projection device 914 is, for example, a projection lens. As the lens constituting the projection device 914, a lens including an axisymmetric surface as a lens surface may be used.

The light guide device 915 is accurately positioned with respect to the projection device 914, for example, by being screwed to a lens barrel of the projection device 914. The light guide device 915 includes, for example, an image light guide member 916 that guides image light, and a transparent member 918 for see-through.

The image light emitted from the projection device 914 enters the image light guide member 916. The image light guide member 916 is a prism that guides the image light toward the eye of the viewer. The image light incident on the image light guide member 916 is repeatedly reflected by the inner surface of the image light guide member 916 and then reflected by a reflective layer 917 to be emitted from the image light guide member 916. The image light emitted from the image light guide member 916 reaches the eye of the viewer. In the illustrated example, the reflective layer 917 reflects the image light in the +Y-axis direction. The reflective layer 917 is made of, for example, a metal or a dielectric multilayer film. The reflective layer 917 may be a half mirror.

The transparent member 918 is adjacent to the image light guide member 916. The transparent member 918 is fixed to the image light guide member 916. The outer surface of the transparent member 918 is, for example, continuous with the outer surface of the image light guide member 916. The transparent member 918 allows the viewer to see through external light. In addition to the function of guiding the image light, the image light guide member 916 also has a function of allowing the viewer to see through the external light.

The light-emitting device according to the exemplary embodiment described above can also be used for other than a projector, a display, and a head-mounted display. The light-emitting device according to the above-described exemplary embodiment is used as a light source of, for example, indoor or outdoor lighting, a laser printer, a scanner, an on-vehicle light, a sensing device using light, and a communication device.

The above-described exemplary embodiments and modifications are merely examples, and the present disclosure is not limited thereto. For example, it is also possible to appropriately combine the exemplary embodiments and the modifications.

The present disclosure includes substantially the same configuration as the configuration described in the exemplary embodiment, for example, a configuration having the same function, method, and result, or a configuration having the same advantage and effect. In addition, the present disclosure includes a configuration in which a non-essential part of the configuration described in the exemplary embodiment is replaced. In addition, the present disclosure includes a configuration having the same operational effect as that of the configuration described in the exemplary embodiment or a configuration capable of achieving the same advantage. In addition, the present disclosure includes a configuration in which a known technique is added to the configuration described in the exemplary embodiment.

The following contents are derived from the above-described exemplary embodiment and modifications.

An aspect of a light-emitting device includes: a substrate; a first semiconductor portion having a first conductivity type; a first columnar portion and a second columnar portion each including a second semiconductor portion having a second conductivity type different from the first conductivity type, a third semiconductor portion having the first conductivity type and provided between the first semiconductor portion and the second semiconductor portion, and a quantum well layer provided between the second semiconductor portion and the third semiconductor portion; a first electrode provided between the first columnar portion and the substrate; a second electrode provided between the second columnar portion and the substrate; and a conductive member electrically coupling the second electrode and the first semiconductor portion, wherein each of the first columnar portion and the second columnar portion protrudes from the first semiconductor portion toward a side of the substrate, the second semiconductor portion is provided between the substrate and the quantum well layer, the first electrode is electrically coupled to the second semiconductor portion of the first columnar portion, and the second electrode is electrically coupled to, via the conductive member and the first semiconductor portion, the third semiconductor portion of the first columnar portion.

According to the light-emitting device, it is possible to reduce the difference between the position of the first surface of the first electrode on the side opposite to the first semiconductor portion and the position of the second surface of the second electrode on the side opposite to the first semiconductor portion in the stacking direction of the second semiconductor portion and the quantum well layer.

In an aspect of the light-emitting device, a height of the first columnar portion and a height of the second columnar portion may be the same.

According to the light-emitting device, it is possible to reduce the difference between the position of the first surface of the first electrode and the position of the second surface of the second electrode in the stacking direction.

An aspect of the light-emitting device may further include an insulating layer covering a side surface of the first columnar portion.

According to the light-emitting device, the first columnar portion can be protected by the insulating layer.

In an aspect of the light-emitting device, a material of the conductive member may be platinum.

According to the light-emitting device, the conductive member can be formed by an ALD method.

In an aspect of the light-emitting device, a height of the first electrode and a height of the second electrode may be the same.

According to the light-emitting device, it is possible to reduce the difference between the position of the first surface of the first electrode and the position of the second surface of the second electrode in the stacking direction.

In an aspect of the light-emitting device, the number of the first columnar portions may be greater than or equal to the number of the second columnar portions.

According to the light-emitting device, the intensity of the emitted light can be increased.

An aspect of a projector includes the aspect of the light-emitting device.

An aspect of a display includes the aspect of the light-emitting device.

An aspect of a head-mounted display includes the aspect of the light-emitting device.

What is claimed is:

1. A light-emitting device comprising:
a substrate;
a first semiconductor portion having a first conductivity type;
a first columnar portion and a second columnar portion each including a second semiconductor portion having a second conductivity type different from the first conductivity type, a third semiconductor portion having the first conductivity type and provided between the first semiconductor portion and the second semiconductor portion, and a quantum well layer provided between the second semiconductor portion and the third semiconductor portion;
a first electrode provided between the first columnar portion and the substrate;
a second electrode provided between the second columnar portion and the substrate; and
a conductive member electrically coupling the second electrode and the first semiconductor portion, wherein
each of the first columnar portion and the second columnar portion protrudes from the first semiconductor portion toward a side of the substrate,
the second semiconductor portion is provided between the substrate and the quantum well layer,
the first electrode is electrically coupled to the second semiconductor portion of the first columnar portion, and
the second electrode is electrically coupled to, via the conductive member and the first semiconductor portion, the third semiconductor portion of the first columnar portion.

2. The light-emitting device according to claim 1, wherein
a height of the first columnar portion and a height of the second columnar portion are the same.

3. The light-emitting device according to claim 1, further comprising an insulating layer covering a side surface of the first columnar portion.

4. The light-emitting device according to claim 1, wherein
a material of the conductive member is platinum.

5. The light-emitting device according to claim 1, wherein
a height of the first electrode and a height of the second electrode are the same.

6. The light-emitting device according to claim 1, wherein
the number of the first columnar portions is greater than or equal to the number of the second columnar portions.

7. A projector comprising the light-emitting device according to claim 1.

8. A display comprising the light-emitting device according to claim 1.

9. A head-mounted display comprising the light-emitting device according to claim 1.
